(19) United States
(12) Patent Application Publication
(10) Pub. No.: US 2014/0165905 A1
(43) Pub. Date: Jun. 19, 2014

(54) APPARATUS FOR FABRICATING INGOT AND METHOD FOR FABRICATING INGOT

(71) Applicants: Bum Sup Kim, Seoul (KR); Chang Hyun Son, Seoul (KR)

(72) Inventors: Bum Sup Kim, Seoul (KR); Chang Hyun Son, Seoul (KR)

(73) Assignee: LG INNOTEK CO., LTD., Seoul (KR)

(21) Appl. No.: 14/236,004

(22) PCT Filed: Jul. 26, 2012
(86) PCT No.: PCT/KR2012/005990

§ 371 Date: Jan. 29, 2014

(30) Foreign Application Priority Data
Jul. 29, 2011 (KR) 10-2011-0076285

(51) Int. Cl. C30B 23/02; C30B 35/00

(52) U.S. Cl. CPC C30B 23/02; C30B 35/002
USPC 117/84; 118/715

(57) ABSTRACT

Disclosed are an apparatus for fabricating an ingot and a method for fabricating the ingot. The apparatus comprises a crucible to receive a source material, and a guide member over the source material. The guide member comprises a source material feeding part.

### TECHNICAL FIELD

The disclosure relates to an apparatus for fabricating an ingot and a method for fabricating the ingot.

### BACKGROUND ART

In general, materials are very important factors to determine the property and the performance of final products in the electric, electronic and mechanical industrial fields.

SiC represents the superior thermal stability and superior oxidation-resistance property. In addition, the SiC has the superior thermal conductivity of about 4.6 W/Cm° C., so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC by using a seed, a seeded growth sub-limation scheme has been suggested. In this case, after putting SiC powder serving as a source material in a crucible, an SiC single crystal serving as a seed is provided over the source material. In addition, the temperature gradient is formed between the source material and the seed, so that the source material in the crucible is diffused toward the seed and re-crystallized to grow a single crystal.

### DISCLOSURE OF INVENTION

### Technical Problem

The embodiment can grow a high-quality single crystal.

### Solution to Problem

According to the embodiment, there is provided an apparatus for manufacturing an ingot, which comprises a crucible to receive a source material, and a guide member over the source material. The guide member comprises a source material feeding part.

### Advantageous Effects of Invention

As described above, the apparatus for fabricating the ingot comprises a guide member. The guide member may be provided along an inner lateral side of the crucible. Therefore, the guide member narrows a moving path of sublimated SiC gas to concentrate the diffusion of the sublimated SiC gas onto the seed. Thus, the growth rate of the ingot can be improved.

The inner diameter of the guide member may be smaller than the diameter of the seed. Accordingly, the gas sublimated from the source material can be prevented from being moved to the edge of the seed. Therefore, the guide member can prevent a crystal from being grown from the edge of the seed. In other words, the guide member can prevent a multi-crystal from being grown from the edge of the seed. Therefore, an ingot having a high-quality single crystal can be grown without a multi-crystal region. According to the related art, since the multi-crystal is grown at the edge of the seed, the multi-crystal must be removed from the edge of the seed after the ingot has been grown. According to the embodiment, the time and the power required for removing the multi-crystal can be reduced.

The guide member comprises a source material feeding part, and the SiC may be sublimated from the source material feeding part. Accordingly, the source material can be more smoothly fed, so that the growing rate of the ingot 190 can be enhanced. In addition, the source material is exhausted through the source material feeding part, so that the graphitization of the ingot can be minimized. Accordingly, the failure probability of the growth of the ingot can be minimized.

In addition, the guide member comprises the same material as that constituting the ingot, thereby preventing the stress of the ingot during the growing of the ingot and preventing impurities such as carbon from being introduced into the ingot.

In addition, the guide member can prevent the heat of the crucible from being transferred to the seed holder and the edge of the seed. In other words, the guide member can prevent heat from being transferred to the edge of the ingot grown from the seed.

Accordingly, the temperature difference between the central portion of the seed and the edge of the seed can be reduced. In other words, the temperature of the seed can be uniformly maintained. Accordingly, the stress and the defects can be minimized at the edge of the seed. In addition, the central portion of the ingot grown from the seed can be prevented being formed in the convex shape due to the temperature difference between the central portion and the edge of the seed. The ingot may be more effectively available.

### BRIEF DESCRIPTION OF DRAWINGS

FIG. 1 is a sectional view showing an apparatus for manufacturing an ingot according to the embodiment; and

FIG. 2 is a sectional view showing a method for growing the ingot according to the embodiment.

### MODE FOR THE INVENTION

In the description of the embodiments, it will be understood that, when a layer (or film), a region, a pattern, or a structure is referred to as being “on” or “under” another layer (or film), another region, another pad, or another pattern, it can be “directly” or “indirectly” on the other layer (or film), region, pad, or pattern, or one or more intervening layers may also be present. Such a position of the layer has been described with reference to the drawings.

The thickness and size of each layer (film), region, pattern, or structure shown in the drawings may be exaggerated, omitted or schematically drawn for the purpose of convenience or clarity. In addition, the size of each layer (film), region, pattern, or structure does not utterly reflect an actual size.

Hereinafter, the embodiment of the disclosure will be described in detail with reference to accompanying drawings.

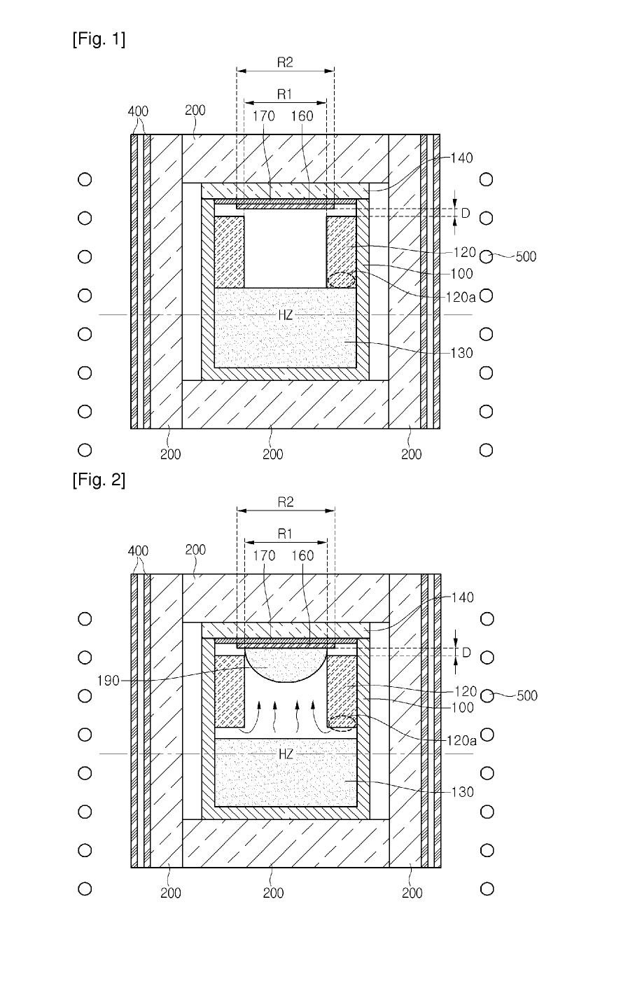

An apparatus for fabricating an ingot 190 and a method for fabricating the ingot 190 according to the embodiment will be described in detail with reference to FIGS. 1 and 2. FIG. 1 is a sectional view showing the apparatus for fabricating the ingot 190 according to the embodiment, and FIG. 2 is a sectional view showing a method of growing the ingot 190 according to the embodiment.

Referring to FIGS. 1 and 2, the apparatus for fabricating the ingot 190 according to the embodiment comprises a crucible 100, a top cover 140, a seed holder 170, a guide member 120, an adiabatic material 200, a quartz tube 400, and a heat induction part 500.

The crucible 100 receives source materials 130 therein.

The crucible 100 has a cylindrical shape to receive the source materials 130.

The crucible 100 may comprise a material having the melting point higher than the sublimation temperature of the SiC.

For example, the crucible 100 can be manufactured by using graphite.

In addition, the crucible 100 can be manufactured by coating a material having the melting point higher than the sublimation temperature of the SiC on the graphite. Preferably, a material, which is chemically inert with respect to silicon and hydrogen at the growth temperature for the SiC ingot 190, is used as the material coated on the graphite. For instance, the material may comprise a metal carbide or a metal nitride. In particular, a mixture including at least two of Ta, Hf, Nb, Zr, W and V and carbide including carbon can be coated on the graphite. Further, a mixture including at least two of Ta, Hf, Nb, Zr, W and V and nitride including nitrogen can be coated on the graphite.

The source materials 130 may comprise silicon and carbon. In more detail, the source materials 130 may comprise a silicon carbide compound. The crucible 100 may receive SiC powders or polycarbosilane.

The top cover 140 is positioned at the upper portion of the crucible 100. The top cover 140 can seal the crucible 100. The top cover 140 may comprise graphite.

The seed holder 170 is located at a lower end of the top cover 140. The seed holder 170 may hold the seed 160. The seed holder 170 may comprise high concentration graphite.

The seed 160 is attached to the seed holder 170. Accordingly, the ingot 190 can be prevented from being grown to the top cover 140 by attaching the seed 160 to the seed holder 170. However, the embodiment is not limited thereto, but the seed 160 may be directly attached to the top cover 140.

Thereafter, the guide member 120 may be provided in the crucible 100. The guide member 120 may be provided over the source material 130. The guide member 120 may extend in a longitudinal direction of the crucible 100. In other words, the guide member 120 may extend from the surface of the source material 130 to the seed 160.

The guide member 120 may be spaced apart from the seed 160. However, the embodiment is not limited thereto. Accordingly, the guide member 120 may make contact with the seed 160. Accordingly, the distance D between the seed 160 and the guide member 120 may be in the range of 0 mm to 3 mm.

The guide member 120 may be provided along an inner lateral side of the crucible 100. Therefore, the guide member 120 can guide silicon carbide (SiC) gas sublimated from the source material 130. In other words, the guide member 120 narrows a moving path of the diffusion of sublimated SiC gas to concentrate the sublimated SiC gas onto the seed 160. Thus, the growth rate of the ingot 190 may be improved.

The guide member 120 may have a ring shape having inner and outer diameters.

An inner diameter R1 of the guide member 120 may be smaller than a diameter R2 of the seed 160. In more detail, the inner diameter R1 of the guide member 120 may be 0.5 mm to 1 mm smaller than the diameter R2 of the seed 160.

Accordingly, the gas sublimated from the source material 130 can be prevented from being moved to the edge of the seed 160. Therefore, the guide member 120 can prevent a crystal from being grown from the edge of the seed 160. In other words, the guide member 120 can prevent a multi-crystal from being grown from the edge of the seed 160. Therefore, an ingot having a high-quality single crystal can be grown without a multi-crystal region. According to the related art, since the multi-crystal is grown at the edge of the seed 160, the multi-crystal must be removed from the edge of the seed 160 after the ingot 190 has been grown. According to the embodiment, the time and the power required for removing the multi-crystal can be reduced.

The guide member 120 may comprise a material that can endure a high temperature. In particular, the guide member 120 may comprise SiC. In more detail, the guide member 120 may comprise sintered body.

The guide member 120 comprises a source material feeding part 120a. The source material feeding part 120a may be provided at a lower portion of the guide member 120. In detail, the source material feeding part 120a may be provided closely to the source material 130. In more detail, the source material feeding part 120a may be provided in the vicinity of a hot zone HZ.

The source material feeding part 120a may feed a source material to the seed 160. In other words, since the guide member 120 comprises SiC, the SiC gas may be supplied to the seed 160. In detail, the source material can be fed from the source material feeding part 120a provided in the vicinity of the hot zone (HZ) due to the heating of the crucible 100. In other words, the SiC gas may be sublimated from the source material feeding part 120a. Therefore, the source material can be more smoothly fed, so that the growing rate of the ingot 190 can be enhanced. In addition, the source material is exhausted through the source material feeding part 120a, so that the graphitization of the ingot 190 can be minimized. Accordingly, the failure probability of the growth of the ingot can be minimized.

In addition, the guide member 120 comprises the same material as that constituting the ingot 190, thereby preventing the stress of the ingot during the growing of the ingot 190 and preventing impurities such as carbon from being introduced into the ingot 190.

In addition, the guide member 120 can prevent the heat of the crucible 100 from being transferred to the seed holder 170 and the edge of the seed 160. In other words, the guide member 120 can prevent heat from being transferred to the edge of the ingot 190 grown from the seed 160.

Accordingly, the temperature difference between the central portion of the seed 160 and the edge of the seed 160 can be reduced. In other words, the temperature of the seed 160 can be uniformly maintained. Accordingly, the stress and the defects can be minimized at the edge of the seed 160. In addition, the central portion of the ingot 190 grown from the seed 160 can be prevented being formed in the convex shape due to the temperature difference between the central portion and the edge of the seed 160. The ingot 190 may be more effectively available.

The adiabatic material 200 surrounds the crucible 100. The adiabatic material 200 keeps the temperature of the crucible 100 to the level of the crystal growth temperature. Since the crystal growth temperature of the SiC is significantly high, graphite felt may be used as the adiabatic material 200. In detail, the adiabatic material 200 may comprise a cylindrical graphite felt having a predetermined thickness prepared by compressing graphite fiber. In addition, the adiabatic material 200 may be prepared as a plurality of layers surrounding the crucible 100.

The quartz tube 400 is positioned at an outer peripheral surface of the crucible 100. The quartz tube 400 is fitted around the outer peripheral surface of the crucible 100. The quartz tube 400 may block heat transferred into a single crystal growth apparatus from the heat induction part 500. The quartz tube 400 is a hollow tube and cooling water may circulate through an inner space of the quartz tube 400.

The heat induction part 500 is positioned outside the crucible 100. For example, the heat induction part 500 may be an RF induction coil. As RF current flows through the RF induction coil, the crucible 100 can be heated. In other words, the source materials 130 contained in the crucible 100 can be heated to the desired temperature.

The central portion of the heat induction part 500, which is induction heated, is formed at a position lower than the central portion of the crucible 100. Thus, the temperature gradient may be formed in the crucible 100 such that an upper portion and a low portion of the crucible 100 may have temperatures different from each other. That is, a hot zone (HZ), which is the center of the heat induction part 500, is located at a low position relative to the center of the crucible 100 so that the temperature of the low portion of the crucible 100 is higher than that of the upper portion of the crucible 100 about the hot zone (HZ). Further, the temperature is increased from the central portion to the outer peripheral portion of the crucible 100. Due to the temperature gradient, the silicon carbide source material 130 is sublimated and the sublimated silicon carbide gas moves to a surface of the seed 170 having the relatively low temperature. Thus, the silicon carbide gas is grown in a single crystalline structure through the recrystallization.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible to receive a source material;
a seed over the source material; and
a guide member over the source material,
wherein the guide member comprises a source material feeding part.

2. The apparatus of claim 1, wherein the guide member comprises silicon carbide (SiC).

3. The apparatus of claim 2, wherein the guide member comprises a silicon carbide sintered body.

4. The apparatus of claim 1, wherein the source material feeding part is provided at a lower portion of the guide member.

5. The apparatus of claim 1, wherein the guide member is provided along an inner lateral side of the crucible.

6. The apparatus of claim 1, wherein the guide member has a ring shape having an inner diameter and an outer diameter.

7. The apparatus of claim 13, wherein the inner diameter of the guide member is 0.5 mm to 1 mm smaller than the diameter of the seed.

8. The apparatus of claim 14, wherein a distance between the seed and the guide member is in a range of 0.01 mm to 3 mm.

9. A method for fabricating an ingot, the method comprising:
preparing a crucible to receive a source material;
providing a guide member over the source material; and
growing the ingot by sublimating silicon carbide gas from the source material and the guide member.

10. The method of claim 9, wherein the guide member comprises a source material feeding part, and the silicon carbide gas is sublimated from the source material feeding part.

11. The apparatus of claim 5, further comprising a seed over the source material.

12. The apparatus of claim 5, wherein the guide member extends in a longitudinal direction of the crucible.

13. The apparatus of claim 6, wherein the inner diameter of the guide member is smaller than a diameter of the seed.

14. The apparatus of claim 11, wherein the seed is spaced apart from the guide member.

15. The apparatus of claim 11, wherein the seed makes contact with the guide member.

16. The apparatus of claim 1, wherein silicon carbide gas is sublimated from the source material feeding part.
